(19) United States
(12) Patent Application Publication
(10) Pub. No.: US 2007/0047355 A1
(43) Pub. Date: Mar. 1, 2007

(54) METHOD FOR DETECTING A LEAKAGE CURRENT OF A SEMICONDUCTOR MEMORY

(75) Inventors: Herbert Benzinger, Munchen (DE); Tobias Graf, Neubiberg (DE); Joerg Kliewer, Munchen (DE); Manfred Proell, Dorfen (DE); Stephan Schroeder, Munchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: QIMONDA AG, Munich (DE)

(21) Appl. No.: 11/467,740

(22) Filed: Aug. 28, 2006

(30) Foreign Application Priority Data
Aug. 29, 2005 (DE) 10 2005 040 882.6

(51) Int. Cl. G11C 7/02

(52) U.S. Cl. 365/207

(57) ABSTRACT

A method for detecting a leakage current in a bit line of a semiconductor memory is disclosed. In one embodiment, the method includes isolating the connection of a sense amplifier from a bit line via an isolation transistor, reading out a memory cell to the bit line, waiting until a predetermined delay time has elapsed, so that a leakage current measurably changes the voltage on the bit line within the delay time. The sense amplifier is short circuited with the bit line via the isolation transistor. The voltage on the bit line is collected by the sense amplifier, and compared with a reference voltage so as to detect the leakage current.

### CROSS-REFERENCE TO RELATED APPLICATIONS

This Utility Patent Application claims priority to German Patent Application No. DE 10 2005 040 882.6 filed on Aug. 29, 2005, which is incorporated herein by reference.

### BACKGROUND

The invention provides a method for detecting a leakage current in a bit line of a semiconductor memory. In one embodiment, the semiconductor memory includes a sense amplifier and an isolation transistor. The isolation transistor is connected between the bit line to be tested and the sense amplifier. By means of the isolation transistor, the bit line can be isolated from the sense amplifier or connected to the sense amplifier as required.

The invention further provides a semiconductor memory and in particular to a DRAM (Dynamic Random Access Memory).

In DRAMs, the memory cells, which consist substantially of capacitors, are connected to bit lines so as to transmit a data value to be read out from a memory cell or to be read into a memory cell. During the reading out of a memory cell, an access transistor connected with the capacitor of a memory cell is connected through by the activation of a word line, and the charge state stored in the capacitor is applied to the bit line. Subsequently, the weak signal coming from the capacitor will be amplified by a sense amplifier. The sense amplifier includes complementary signal inputs. The bit lines connected with these signal inputs are referred to as bit line and complementary bit line.

In today's DRAMS, the sense amplifiers are, as a rule, used in a divided manner so as to save chip space. A sense amplifier is used for the reading out of both a memory cell that is arranged at the left and at the right along a bit line adjacent to the sense amplifier.

Prior to the reading out of the memory cells, the corresponding bit line sections, i.e. the corresponding sections of the non-complementary bit line and of the complementary bit line, are precharged, by precharge/equalize circuits that are connected with the bit lines, to an equal potential. Thus it is ensured that, prior to the reading out, no differences occur between the potential of a section of the bit line and the section of the complementary bit line assigned thereto, which might overlap or distort the small amount of charge transmitted to the bit line by the capacitor of a memory cell during reading out. Directly before the reading out of the memory cells, the precharge/equalize circuits that are adapted to be connected with the bit line sections, the memory cell to be read out, and the sense amplifier, are switched off.

Known DRAMs moreover comprise isolation transistors that serve to decouple the sense amplifier during the reading out of the cells from that side that is not to be read out. At the gate connections of the isolations transistors, which consist, as a rule, of two NMOS-FETs whose source-drain-paths are adapted to interrupt the corresponding bit line sections, precharge voltages are applied in the case of known DRAMs beyond the read and write cycles. Directly prior to the reading out of a memory cell, the one side of the sense amplifier that would be connectable with the memory cell that is not to be read out is decoupled from the bit lines in that the gate connections of the isolation transistors positioned at that side of the sense amplifier are set to ground potential. At the same time, the other side of the sense amplifier is coupled in an improved manner in that the gate voltage present at the gate connections of the isolation transistors positioned at the other side of the sense amplifier is slightly increased from its initial value.

The memory field of DRAMs consists of rows (word lines) and columns (bit lines). On memory access, a word line is first of all activated. Thus, the memory cells arranged in a row are each connected conductively with a bit line. Consequently, the charge of the memory cell is transferred to the adjacent word line and bit line. Corresponding to the ratio of word line and bit line capacitance, the potential of the bit line is changed. The charge on the bit line gets to the connected sense amplifier via the through-connected isolation amplifier. The bit line voltage is compared with a constant reference voltage, and is subsequently amplified.

Conventional DRAMs consist of a plurality of adjacent memory fields. Within the memory fields there are arranged a plurality of memory cells which are each adapted to be controlled via the word lines and the bit lines. The division into a plurality of memory fields is performed since the size of the memory fields is restricted by the length of the physical bit line. If the bit line is extended, its capacitance will increase. This, again, has as a consequence that the voltage difference to be collected by the sense amplifier becomes smaller. On the other hand, the capacitance of the memory cells cannot be increased so as to store more charge since this would increase the access time to the memory cells. The capacitance of the memory cell is restricted by the oxide thickness and by the trench depth. Accordingly, the length of the bit line is restricted such that the sense amplifiers are adapted to collect the voltage that has been read out.

A plurality of sense amplifiers are arranged between adjacent memory fields. Each bit line pair of a memory field is connected to a sense amplifier. The word lines are each assigned to a memory cell field.

Two bit line pairs are connected to each sense amplifier. The connected bit line pairs come from two adjacent memory fields. This arrangement is referred to as “shared sense amplifier” since two bit line pairs jointly share one sense amplifier. The sense amplifier may read out and amplify either the first bit line pair or the second bit line pair. Isolation transistors are connected between the bit line pairs and the sense amplifier. When the sense amplifier reads out the voltage difference of one bit line pair, the other bit line pair is decoupled or isolated from the sense amplifier.

FIG. 1 illustrates a known arrangement of sense amplifiers. The sense amplifiers 12, 14, and 16 are each arranged in arrays one below the other. Reference sign 12 designates the left sense amplifiers in FIG. 1. Reference signs 14 and 16 designate the middle and the right sense amplifiers in FIG. 1. Two pairs of bit lines 18 start out from each of the sense amplifiers 12, 14, and 16. A bit line length 10 defines the distance between the arrays of sense amplifiers.

Bit line pairs 18 are arranged between the arrays of sense amplifiers 12, 14, and 16. The bit line pairs 18 are connected with a plurality of (not illustrated) memory cells. The sense amplifiers are provided to amplify the potential difference between an upper and a lower bit line 18a and 18b. As a rule, the bit lines 18a and 18b of each bit line pair 18 are on the same potential. A voltage difference is caused by charge being transferred from a memory cell to one of the bit lines. The resulting voltage difference is collected by the sense amplifiers 12, 14, and 16 and is output in an amplified manner.

The memory fields between the sense amplifiers are integrated circuits with a very high device density. Due to manufacturing defects, short circuits may occur between adjacent bit lines or between bit lines and crossing word lines. The short circuits form leakage paths that may result in a reduction of the bit line signal prior to the evaluation by the sense amplifier. Consequently, the voltage difference generated during the reading out of a memory cell is reduced. The sense amplifier receives a very weak signal which it is not capable of collecting and amplifying. Thus, the memory cell cannot be read out correctly, so that the memory is not functional.

The short circuit leakage currents of the bit lines may increase over the duration of operation of the semiconductor memory. Accordingly, the functionality of the memory will be jeopardized only at a point in time that may be months from the date of delivery. This kind of degradation defects is considered as particularly critical by memory customers.

In order to avoid that defective semiconductor memories are delivered, a check is made for whether short circuits between the bit lines exist. Due to the increase in the leakage current during the duration of operation of the semiconductor memory it is necessary to also detect very small leakage currents that do not yet impair the function of the semiconductor memory. Conventionally, the test consists in that the memory cells are read out to the bit lines and in that the voltage difference on the bit lines is collected by means of the sense amplifiers. If the measured voltage difference under-runs a reference value, the bit line is classified as defective. Since also very small leakage currents are to be detected, the voltage difference is measured after a predetermined delay time (Set Delay Time SDT) only. The longer the leakage current flows, the smaller is the voltage difference between the bit lines. The deviation of the measured voltage value from the reference value is the greater the longer the delay time SDT is. A great delay time SDT thus enables also the measurement of small leakage currents.

FIG. 2 illustrates a conventional sense amplifier 20 that is connected to four bit lines 22, 24, 26, and 28. The bit lines 22, 24 and the bit lines 26 and 28 each form a bit line pair. The sense amplifier 20 is provided for collecting and amplifying the voltage differences between the bit lines of a bit line pair. An isolation transistor 30, 32, 34, 36 is connected between each of the bit lines 22, 24, 26, 28 and the sense amplifier. When the sense amplifier 20 is to collect the voltage difference on the right bit line pair consisting of the bit lines 26 and 28, the left bit lines 22 and 24 are electrically isolated from the sense amplifier 20 by means of the isolation transistors 30 and 32. If, vice versa, the left bit lines 22 and 24 are to be evaluated by the sense amplifier 20, the right bit lines 26 and 28 are electrically isolated by means of the isolation transistors 34 and 36.

The structure of the sense amplifier itself is illustrated in FIG. 2. The sense amplifier includes an upper connection line 54 that is connected with the bit lines 22 and 26 via the isolation transistors 30 and 34. The lower connection line 56 is connected with the bit lines 24 and 28 via the isolation transistors 32 and 36. Four transistors are connected between the upper and the lower connection lines 54 and 56. Two n-channel MOSFETs 40 and 42 are illustrated in FIG. 2. Furthermore, two p-channel MOSFETs 44 and 46 are illustrated in FIG. 2. Each of the transistors 40, 42, 44, and 46 includes three connections, namely the source S, the drain D, and the gate G. The n-channel MOSFET 40 is connected through in that a positive voltage is applied to the gate connection. Thus, there is formed a thin conductive region consisting of electrons in the p-doped region below the gate G. The n-channel enables a current flow from the source connection S to the drain connection of the n-channel MOSFET. The p-channel MOSFET is connected through in that a negative voltage is applied to the gate connection G.

The source connection S of the n-channel MOSFET 40 and of the p-channel MOSFET 44 is each connected with the upper connection line 54. The gate connection G of the n-channel MOSFET 40 and of the p-channel MOSFET 44 is each connected with the lower connection line 56. Consequently, the gate connection of the transistors 40 and 44 and the lower connection line 56 are balanced on the same potential. When the n-channel MOSFET 40 is connected through, the p-channel MOSFET is locking, and vice versa. The source connections S of the transistors 40 and 44 are balanced with the same voltage.

The drain connections D of the n-channel MOSFET 42 and of the p-channel MOSFET 46 are both connected with the lower connection line 56. The gate connections of the transistors 42 and 46 are each connected with the upper connection line 54. Therefore, either the n-channel MOSFET 42 or the p-channel MOSFET 46 is connected through. The drain connections D of the transistors 42 and 46 are connected with the lower connection line 56 and are consequently balanced on the same potential. The drain connection of the n-channel MOSFET 40 and the source connection of the n-channel MOSFET 42 are connected with each other and form the left output 50 of the sense amplifier. The right output 52 is connected with the drain connection of the transistor 44 and the source connection of the transistor 46.

Either the left isolation transistors 30 and 32 or the right isolation transistors 34 and 36 of the sense amplifier 20 illustrated in FIG. 2 are connected through. The sense amplifier 20 is either connected with the right bit lines 26 and 28 or with the left bit lines 22 and 24. The bit lines 26, 28, 22, and 24 are precharged, i.e. they are on a predetermined potential VBLEQ. If a memory cell is read out, the voltage is increased on the true bit line by Vcell, while the other bit line keeps the potential VBLEQ. In FIG. 2, the bit lines 22 and 26 are true bit lines, while the bit lines 24 and 28 are each charged with the reference voltage VBLEQ. If there is to be evaluated whether a leakage current exists in the right bit lines 26 and 28, the isolation transistors 30 and 32 are locked, while the isolation transistors 34 and 36 are connected through. The charge in a (not illustrated) memory cell is read out to the true bit line 34, so that the voltage on the upper connection line 54 increases to VBLQ+Vcell. The voltage increase Vcell usually amounts to approx. 200 to 300 mV. Prior to the evaluation by the sense amplifier 20, one has the delay time SDT elapse so as to be able to detect small leakage currents. During this period, the p-channel MOSFET 44 is locked. In the ideal case, no current flows from the upper connection line through the transistor 44. This is because a reduction of the voltage on the upper connection line 54 is to be evaluated as an indication of a leakage current between the bit lines. However, for each p-channel MOSFET there exists a threshold voltage Uth between the source connection and the gate connection. If the threshold voltage is reached or exceeded, a current possibly flows via the source connection and the drain connection of the p-channel MOSFET 44 to the point 52 that also lies on VBLEQ potential. This additional leakage current aggravates an examination of the bit lines since the picking off of the voltage on the upper connection line 54 is caused both by the leakage current in the bit lines and by the leakage current in the sense amplifier itself.

For these and other reasons, there is a need for the present invention.

### SUMMARY

The present invention provides a method for detecting a leakage current in a bit line of a semiconductor memory. In one embodiment, the method includes isolating the connection of a sense amplifier from the bit line by an isolation transistor, reading out a memory cell to the bit line, and waiting until a predetermined delay time has elapsed, so that a leakage current measurably changes the voltage on the bit line within the delay time. The sense amplifier is short circuited with the bit line by the isolation transistor. The voltage on the bit line is collected by the sense amplifier. The collected voltage is compared with a reference voltage so as to detect the leakage current.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 a conventional arrangement of sense amplifiers in a semiconductor memory,

FIG. 2 illustrates a conventional sense amplifier that is connected to two bit line pairs via two isolation transistor pairs,

FIG. 3 illustrates a sense amplifier electrically decoupled from the bit lines by the isolation transistor pairs,

FIG. 4 illustrates a sense amplifier controlled in accordance with one embodiment of the present invention,

FIG. 5 illustrates a flowchart illustrating one method in accordance with one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a method for the detection of a leakage current in a bit line of a semiconductor memory by means of which it is possible to reliably detect the leakage current.

The method serves to detect a leakage current in a bit line of a semiconductor memory. The semiconductor memory includes a sense amplifier and an isolation transistor. The isolation transistor is connected between the bit line to be tested and a connection of the sense amplifier. By means of the isolation transistor, the bit line can be isolated from the sense amplifier, or the bit line can be connected to the sense amplifier, as required.

In one embodiment of the invention, the connection of the sense amplifier is isolated from the bit line by means of the isolation transistor. In this state, the voltage on the bit line cannot be influenced by parasitic leakage currents of the sense amplifier. Next, a memory cell is read out to the bit line, and the elapse of a predetermined delay time is waited for. The voltage on the bit line remains unchanged if no leakage currents occur between the bit lines. Leakage currents through the sense amplifier cannot influence the voltage on the bit line since it is electrically isolated from the sense amplifier. The delay time is so long that the leakage current measurably changes the voltage on the bit line. The voltage drop on the bit line is accordingly a measurement for the amount of the leakage current.

After elapse of the delay time, the sense amplifier is short-circuited with the bit line by means of the isolation transistor. The connection of the sense amplifier and the bit line are balanced on the same potential. The sense amplifier is used for measuring the bit line potential as soon as the bit line has been short-circuited with the sense amplifier. Thus, it is prevented that leakage currents through the sense amplifier noticeably influence the voltage collected. Finally, the voltage collected by the sense amplifier is compared with a reference voltage so as to find out whether a leakage current has flown in the bit line during the delay time.

In one embodiment, during the delay time the connection of the sense amplifier is kept on a constant potential. This is, for instance, achieved in that the connection is connected, during the delay time, to a voltage source that keeps the connection at a constant potential. For, if the potential of the connection lies on an unknown or variable potential prior to the short circuit with the bit line, the potential that is being balanced on the bit line and the connection will be influenced.

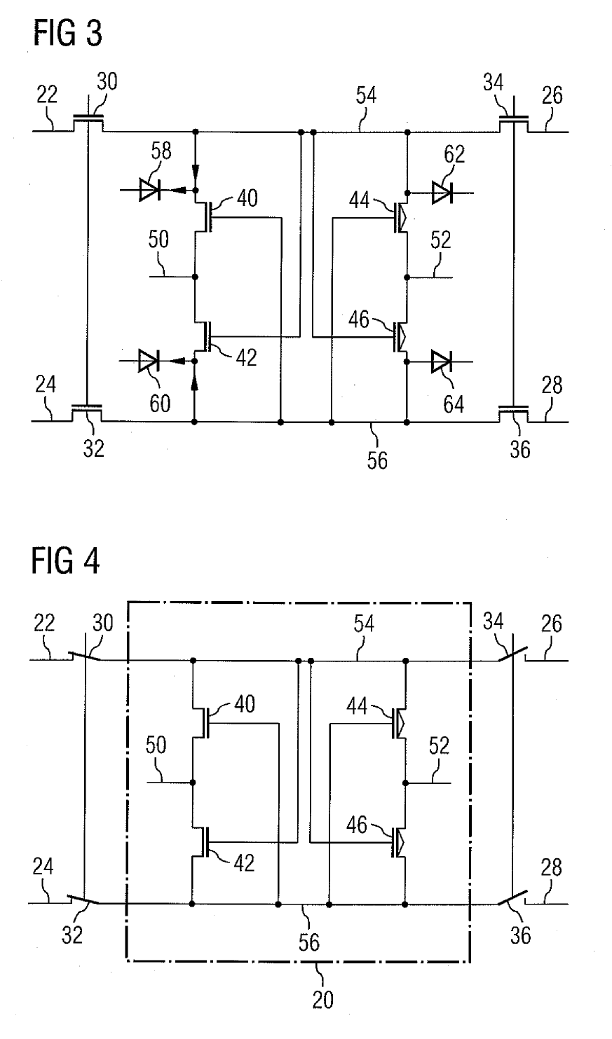

The circuit illustrated in FIG. 3 illustrates the afore-explained problem of a variable connection potential. FIG. 3 illustrates a circuit with the same components as in FIG. 2. The reference signs used in FIG. 3 designate the same objects as in FIG. 2. The circuit of FIG. 3 is in a state in which the isolation amplifiers 30, 32, 34, and 36 completely isolate the sense amplifier 20. The connection lines 54 and 56 are decoupled from any voltage sources, i.e. the connection lines “float”. Prior to the isolation of the sense amplifier 20, both connection lines 54 and 56 were precharged on a reference potential VBLEQ. The (not illustrated) voltage sources supply a “equalize signal” so as to keep the lines on the reference potential.

Due to the complete isolation of the sense amplifier from the bit lines 22 and 26, a memory cell voltage Vcell switched on the bit lines cannot be attenuated by the sense amplifier. However, the sense amplifier “floats”, i.e. it is decoupled from any equalizing voltage sources that are each positioned on the bit lines at the right and at the left of the isolation transistors.

The n-channel MOSFET transistors 40 and 42 each comprise a p-doped substrate and n⁺-doped source and drain connections S and D. The p-n⁺ junctions between the sources are diodes that are precharged in locking direction in the operating state. This is because a current flow between the substrate and the source or drain connection is to be avoided. The p-doped substrate is grounded in the operating state. This means that the source-substrate junction of the transistor 40 is a diode 58 that is operated in locking direction; a diode 60 in FIG. 3 designates the substrate-source junction of the n-channel MOSFET 42. Although the two diodes 58 and 60 are operated in locking direction, a leakage current may occur. As a rule, the leakage current is caused by the minority charge carriers that are available in the p- and n-doped semiconductors. By and by, the potential on the connection lines 54 and 56 therefore changes. The p-channel MOSFETs 44 and 46 also each comprise parasitic diodes 62 and 64 at the n⁺-p junctions between source and substrate. The leakage current through the diodes 62 and 64 that are operated in locking direction also changes the reference voltage on the connection lines 54 and 56. Therefore, when connecting through a bit line to the sense amplifier after the delay time, a wrong evaluation by the sense amplifier may occur. The sense amplifier registers a reduced potential on the connection lines, which is, however, not caused by the leakage currents in the bit lines, but by the sense amplifier itself

In one embodiment, during the delay time, the connection of the sense amplifier is kept on a constant potential in that the connection is short-circuited with the precharged second bit line. During the delay time, the connection of the sense amplifier may be kept on a constant potential in that the connection is short-circuited with the precharged first bit line.

The equalize circuits that are provided from the outset on the bit lines are used to keep the connection lines of the sense amplifier on a constant potential during the delay time. Thus, leakage currents are offset by the parasitic diodes of the sense amplifier transistors. If the sense amplifier is short-circuited with the bit line to be measured, the connection line is on a defined potential. No more additional voltage source is used, but the voltage sources that are already available and provided for the bit lines are resorted to.

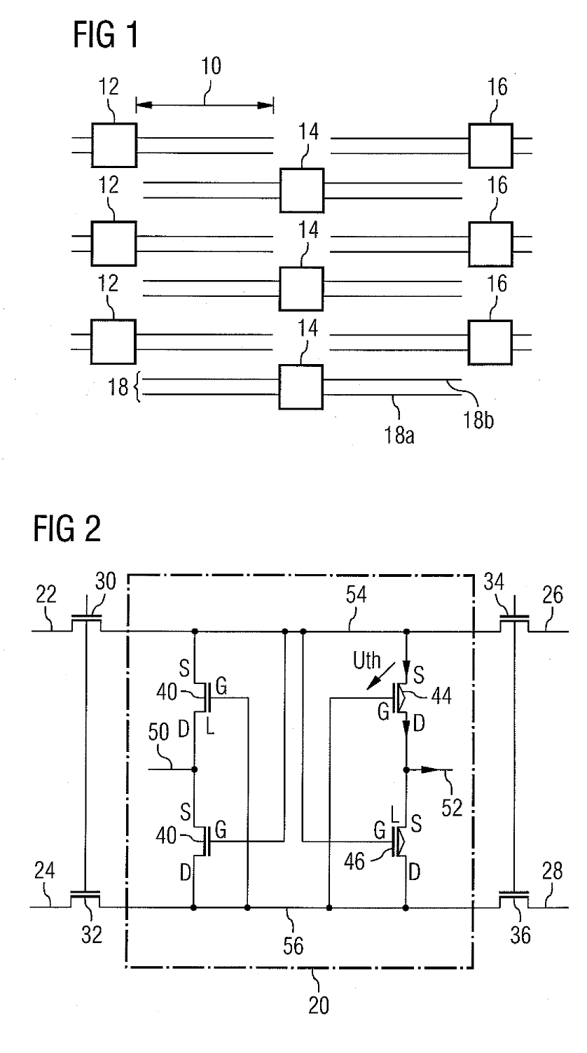

FIG. 1 illustrates a conventional arrangement of sense amplifiers in a semiconductor memory. Three arrays of sense amplifiers 12, 14, and 16 are illustrated side by side. The sense amplifiers 12, 14, and 16 are arranged one below the other within each array. Between the sense amplifiers there are positioned the memory fields in which a plurality of memory cells are each arranged in the form of a matrix. Each memory cell is connected with one of the sense amplifiers via a bit line pair. Each of the sense amplifiers is connected to two complementary bit line pairs.

FIG. 2 illustrates a sense amplifier 20 that is connected to two bit line pairs via two isolation transistor pairs. The left bit line pair includes bit lines 22 and 24, while the right bit line pair includes bit lines 26 and 28. The sense amplifier 20 is connected to the left bit lines via the isolation transistors 30 and 32. The right bit lines are connected to the sense amplifier 20 via isolation transistors 34 and 36. For the upper bit lines 22 and 26, the sense amplifier has a connection line 54, while a lower connection line 56 is provided for the lower bit lines 24 and 28.

Between the upper and lower connection lines 54 and 56 there are connected four transistors 40, 42, 44, and 46. The transistors 40 and 42 are n-channel MOSFETs, while the transistors 44 and 46 are p-channel MOSFETEs. The transistors 40 and 42 are connected in series with the source S and the drain D between the connection lines. The gate G of the transistor 42 is connected with the upper connection line. The lower connection line is connected with the gate G of the transistor 40. The p-channel transistors 44 and 46 are likewise connected in series between the upper and the lower connection lines 56. For the p-channel transistor 44, the threshold voltage Uth is additionally plotted.

FIG. 3 illustrates the sense amplifier of FIG. 2 which is electrically decoupled from the bit lines by the isolation transistor pairs. Identical reference signs in FIGS. 2 and 3 designate the same objects. To this extent, reference is made to the description of FIG. 2. Additionally, parasitic diodes 58, 60, 62, and 64 are plotted in FIG. 3. Each of the diodes 58 to 64 is exactly assigned to one of the transistors 40 to 46. In the normal operating state of the transistors, no current is to flow through any of the diodes 58 to 64. If a current flows nevertheless, this current is referred to as “parasitic”. Hence the term parasitic diode.

The parasitic diodes 58 and 60 of the n-channel MOSFETs are each formed by the junction between the n⁺-doped source and the p-doped substrate of the transistors. The substrate of the n-channel MOSFETs is grounded in operation, so that the diodes 58 and 56 are connected in locking direction. The leakage current in locking direction is the parasitic current through the diode. If the upper and lower connection lines 54 and 56 are in a floating state, their potential gradually decreases due to the leakage current through the parasitic diodes 58 and 60. The parasitic diodes 62 and 64 are formed by the p⁺-n substrate-source junction of the p-channel MOSFETs 62 and 64. These diodes are also operated in locking direction so as to minimize a parasitic current. The parasitic current through the diodes 58 and 60 also influences the voltage on the upper and lower connection lines 54 and 56.

FIG. 5 is a flowchart illustrating one method according to the one embodiment of the invention. In the first process 70, the right bit lines 26 and 28 are isolated from the connection lines 54 and 56. Subsequently, at process block 72, a memory cell is read out to the bit line 26, and at process block 74 the bit lines 22 and 24 are short-circuited with the connection lines 54 and 56.

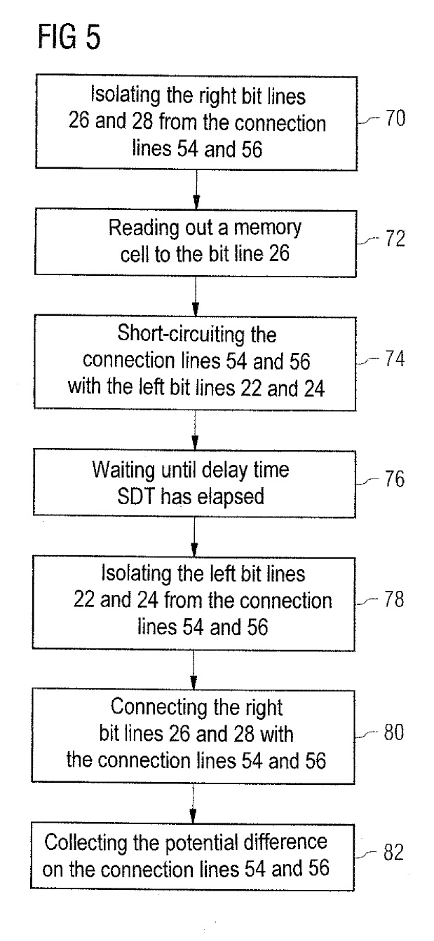

A sense amplifier in this state is illustrated in FIG. 4. The isolation transistors 34 and 36 are connected such that no current can flow from the bit lines 26 and 28 to the sense amplifier. If the voltage on the bit line 26 decreases, this voltage reduction is due to a leakage current in the bit line 26. The bit lines 22 and 24 are both connected with a precharge or equalize circuit. Therefore, the connection lines 54 and 56 are on a well-defined potential. Parasitic currents through the transistors 40, 42, 44, or 46 are balanced by the (not illustrated) equalize circuit.

Once the delay time SDT has elapsed (process 76), the left bit lines 22 and 24 are isolated from the connection lines 54 and 56 in process 78. Directly thereafter, the right bit lines 26 and 28 are short-circuited with the connection lines 54 and 56 in process 80. Now, in process 82, the sense amplifier 20 collects the potential difference on the bit lines 26 and 28 which corresponds in balance to the potential difference on the connection lines 54 and 56.

Process 78 has to be done before process 80. Otherwise, the equalize circuits would influence the voltage on the connected bit lines 26 and 28. This must not happen since the voltage difference on the bit lines is to serve as a measurement for the leakage current in the right bit lines. On the other hand, the time difference between processes 78 and 80 must be kept as small as possible since otherwise the parasitic leakage currents within the sense amplifier 20 might influence the measurement.

After process 80 has been performed, a short period of approx. 6 ns is waited until the sense amplifier collects the potential difference between the upper and the lower connection lines 54 and 56. This period is selected just as large that no more potential difference exists between the connection line 54 and the connected bit line 26, i.e. the true bit line 26 and the connection line 54 are in balance. At the same time, this period has to be as short as possible, so that parasitic leakage currents within the sense amplifier 20 do not distort the measurement.

As a rule, both the bit lines 26 and 28 and the bit lines 22 and 24 are connected to memory cells of a memory filed. The (not illustrated) equalize circuits provided for the bit lines are then used for keeping the voltage on the connection lines 54 and 56 constant during the delay time.

If the sense amplifier 20 should be an edge amplifier that is connected to a memory field on one side only, the isolation transistors and voltage sources have to be provided at that side of the sense amplifier that is not connected. If, in particular, exclusively the right bit lines 26 and 28 are connected to memory cells, the isolation transistors 30 and 32 as well as the lines 22 and 24 must be provided nevertheless. In this case, the lines 22 and 24 do not constitute any bit lines. They are merely provided to be connected with voltage sources so as to keep the connection lines on a constant potential during the delay time.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for operating a semiconductor memory comprising:
isolating a connection of a sense amplifier from a bit line by an isolation transistor;
reading out a memory cell to the bit line;
waiting until a predetermined delay time has elapsed, so that a leakage current measurably changes a voltage on the bit line within the delay time;
short-circuiting the sense amplifier with the bit line by the isolation transistor;
collecting the voltage on the bit line by the sense amplifier; and
using the collected voltage to detect the leakage current.

2. The method according to claim 1, comprising:
detecting the leakage current by comparing the collected voltage to a reference voltage.

3. The method according to claim 1, comprising:
connecting the sense amplifier and the isolation transistor between the bit line to be tested and the connection of the sense amplifier.

4. The method according to claim 3, comprising:
connecting the sense amplifier and the isolation transistor so as to isolate the bit line from the sense amplifier.

5. The method according to claim 3, comprising:
connecting the sense amplifier and the isolation transistor to connect the bit line to the sense amplifier.

6. The method according to claim 1, comprising:
reading out a DRAM memory cell.

7. The method according to claim 1, comprising:
keeping the connection of the sense amplifier on a constant potential during the delay time.

8. A method for detecting a leakage current in a bit line of a semiconductor memory comprising:
connecting a sense amplifier and an isolation transistor between the bit line to be tested and a connection of the sense amplifier so as to isolate the bit line from the sense amplifier or to connect the bit line to the sense amplifier;
isolating the connection of the sense amplifier from the bit line by means of the isolation transistor;
reading out a memory cell to the bit line;
waiting until a predetermined delay time has elapsed, so that a leakage current measurably changes the voltage on the bit line within the delay time;
short-circuiting the sense amplifier with the bit line by means of the isolation transistor; and
collecting the voltage on the bit line by the sense amplifier.

9. The method according to claim 8, comprising keeping the connection of the sense amplifier on a constant potential during the delay time.

10. A method according for detecting a leakage current in a bit line of a semiconductor memory, comprising:
defining the semiconductor memory to include a first and a second bit line which are both connected to the connection of the sense amplifier, a first isolation transistor for isolating the first bit line from the connection, and a second isolation transistor for isolating the second bit line from the connection; and
short-circuiting the sense amplifier with the first bit line so as to collect the voltage on the first bit line, the sense amplifier is isolated from the second bit line by means of the second isolation transistor, and while the sense amplifier is short-circuited with the second bit line so as to collect the voltage on the second bit line, the sense amplifier is isolated from the first bit line by means of the first isolation transistor.

11. The method according to claim 10, comprising wherein the delay time for detecting the leakage current on the first bit line elapses, the connection of the sense amplifier is kept on a constant potential in that the connection is short-circuited with the precharged second bit line, while the delay time for detecting the leakage current on the second bit line elapses, the connection of the sense amplifier is kept on a constant potential in that the connection is short-circuited with the precharged first bit line.

12. A semiconductor memory comprising:
a bit line;
a sense amplifier comprising a connection;
an isolation transistor connected between the bit line to be tested and the connection of the sense amplifier so as to isolate the bit line from the sense amplifier or to connect the bit line to the sense amplifier, as required; and
a control circuit for detecting a leakage current in the bit line of the semiconductor memory, wherein the control circuit is configured to control the semiconductor memory comprising isolating the connection of the sense amplifier from the bit line by means of the isolation transistor, reading out a memory cell to the bit line, predetermining delay time elapses, so that the leakage current measurably changes the voltage on the bit line within the delay time, short-circuiting the sense amplifier with the bit line by means of the isolation transistor, and collecting the voltage on the bit line by the sense amplifier.

13. A DRAM semiconductor memory comprising:
a bit it line
a sense amplifier:
a control circuit for detecting the leakage current of the bit line, including an isolation transistor connected between the bit line and a connection of the sense amplifier, wherein the bit line is configured to be isolated from the sense amplifier via the isolation transistor, the control circuit is configured to read out reading out a DRAM memory cell to the bit line, wait until a predetermined delay time has elapsed, so that a leakage current measurably changes a voltage on the bit line within the delay time, short-circuit the sense amplifier with the bit line by the isolation transistor, collect the voltage on the bit line by the sense amplifier, and use the collected voltage to detect the leakage current.

14. The memory according to claim 13, comprising:
where the control circuit is configured to detect the leakage current by comparing the collected voltage to a reference voltage.

15. The memory according to claim 13, comprising:
where the sense amplifier and the isolation transistor are connected between the bit line to be tested and the connection of the sense amplifier.

16. The memory according to claim 13, comprising:
where the sense amplifier and the isolation transistor are connected so as to isolate the bit line from the sense amplifier.

17. The method according to claim 13, comprising:
where the sense amplifier and the isolation transistor are configured to connect the bit line to the sense amplifier.

18. The method according to claim 13, comprising:
where the control circuit is configured to keep the sense amplifier at a constant potential during the delay time.

19. A semiconductor memory comprising:
means for isolating a connection of a sense amplifier from a bit line by an isolation transistor;
means for reading out a memory cell to the bit line;
means for waiting until a predetermined delay time has elapsed, so that a leakage current measurably changes a voltage on the bit line within the delay time;
means for short-circuiting the sense amplifier with the bit line by the isolation transistor;
means for collecting the voltage on the bit line by the sense amplifier; and
means for using the collected voltage to detect the leakage current.

20. The method according to claim 19, comprising:
means for comparing the collected voltage to a reference voltage to detect the leakage voltage.
